(19) United States
(12) Patent Application Publication
(10) Pub. No.: US 2024/0238936 A1
(43) Pub. Date: Jul. 18, 2024

(54) CHEMICAL MECHANICAL POLISHING (CMP) APPARATUS AND METHOD OF CONTROLLING THEREOF

(71) Applicant: SAMSUNG ELECTRONICS CO., LTD., Suwn-si (KR)

(72) Inventors: Wonkeun CHO, Suwon-si (KR); Donghoon Kwon, Suwon-si (KR)

(73) Assignee: SMSUNG ELECTRONICS CO., LTD., Suwn-si (KR)

(21) Appl. No.: 18/230,528

(22) Filed: Aug. 4, 2023

(30) Foreign Application Priority Data
Jan. 17, 2023 (KR) 10-2023-0006727

(51) Int. Cl. B24B 37/10; B24B 49/14; B24B 53/017; B24B 57/02; H01L 21/67

(52) U.S. Cl. CPC B24B 37/107; B24B 49/14; B24B 53/017; B24B 57/02; H01L 21/67051

(57) ABSTRACT

Provided is a chemical mechanical polishing apparatus including a head part configured to support a wafer, a buffer part on the head part and configured to support a center of the wafer, and a first polishing part that is spaced apart from the buffer part and configured to be on an edge of the wafer.

### CROSS-REFERENCE TO RELATED APPLICATION

This application claims priority to Korean Patent Application No. 10-2023-0006727 filed in the Korean Intellectual Property Office on Jan. 17, 2023, the entirety of which is incorporated herein by reference.

### BACKGROUND

### 1. Field

Embodiments of the present disclosure relate to a chemical mechanical polishing (CMP) apparatus. More particularly, the present disclosure relates to a chemical mechanical polishing apparatus capable of polishing an edge portion of a front surface or a rear surface of a wafer, and a control method thereof.

### 2. Description of Related Art

A chemical mechanical polishing (CMP) apparatus is used in a polishing process to planarize a surface of a semiconductor wafer. In general, semiconductor devices are manufactured by selectively or repeatedly performing processes such as photography, etching, diffusion, chemical vapor deposition (CVD), ion implantation, or metal deposition on a wafer. In this process, the semiconductor wafer undergoes a chemical mechanical polishing (CMP) process such as a planarization process and an etchback process to facilitate formation of a circuit pattern on the surface.

The CMP process mainly directs the back surface of the wafer to a membrane direction, and polishes the front surface where the film material is deposited. While the front surface is polished through frictional force with a pad and a chemical reaction with a slurry, the rear surface is disposed facing the membrane and no polishing is performed, so there is a problem that a bevel film on the edge remains on the rear surface.

### SUMMARY

One or more embodiments provide a chemical mechanical polishing apparatus for removing the bevel film remaining on the edge of the front or rear surface of the wafer.

One or more embodiments also provide a chemical mechanical polishing apparatus to prevent tilting of the wafer and precisely remove the remaining bevel film on the front or rear surface of the wafer.

One or more embodiments also provide a method of controlling a chemical mechanical polishing apparatus having the advantages described above.

According to an aspect of an embodiment, there is provided a chemical mechanical polishing apparatus including a head part configured to support a wafer, a buffer part on the head part and configured to support a center of the wafer, and a first polishing part that is spaced apart from the buffer part and configured to be on an edge of the wafer.

According to another aspect of an embodiment, there is provided a chemical mechanical polishing apparatus including a head part configured to support a wafer such that a surface of the wafer is exposed, a buffer part on the head part and configured to support a center of the surface of the wafer, a first polishing part spaced apart from the buffer part in a radial direction of the wafer and on an edge of the surface of the wafer, and a head supporting part symmetric to the first polishing part with respect to a rotation axis of the buffer part, the head supporting part being configured to support the head part.

According to another aspect of an embodiment, there is provided a control method of a chemical mechanical polishing apparatus including disposing a head part on a buffer part, loading a wafer on the buffer part by moving the wafer between the head part and the buffer part, moving the loaded wafer to be in contact with a membrane in the head part, supplying a slurry from a first slurry supplier to a first polishing pad, and rotating the first polishing pad and the head part and polishing an edge of the wafer.

### BRIEF DESCRIPTION OF DRAWINGS

The above and other aspects, features, and advantages of the embodiments will be more clearly understood from the following detailed description, taken in conjunction with the accompanying drawings, in which:

FIG. 1A is a perspective view of a chemical mechanical polishing apparatus according to an embodiment, FIG. 1B is a cross-sectional view of a chemical mechanical polishing apparatus of FIG. 1A taken along a direction A-A′, and FIG. 1C is a top plan view of a chemical mechanical polishing apparatus of FIG. 1A;

FIG. 2A is a perspective view of a chemical mechanical polishing apparatus according to another embodiment, FIG. 2B is a cross-sectional view of a chemical mechanical polishing apparatus taken along a direction A-A′ of FIG. 2A, and FIG. 2C is a top plan view of a chemical mechanical polishing apparatus of FIG. 2A;

FIG. 3A and FIG. 3B are top plan views of a chemical mechanical polishing apparatus according to an embodiment;

FIG. 4A is a perspective view of a chemical mechanical polishing apparatus according to another embodiment, FIG. 4B is a cross-sectional view of a chemical mechanical polishing apparatus of FIG. 4A taken along a direction A-A′, FIG. 4C is a top plan view of a chemical mechanical polishing apparatus of FIGS. 4A, and 4D is a view showing that a head part is swept;

FIGS. 5A and 5B are top plan views of a chemical mechanical polishing apparatus according to another embodiment;

FIG. 6 is a view showing a buffer part according to an embodiment;

FIGS. 7A, 7B, and 7C are views showing a pattern of a membrane according to an embodiment;

FIGS. 8A, 8B, and 8C are views showing a chemical mechanical polishing apparatus including a cleaning part according to an embodiment;

FIG. 9 is a view showing a chemical mechanical polishing apparatus including a temperature controller according to an embodiment; and

FIGS. 10A, 10B, 10C, 10D, 10E, and 10F are views showing a control method of a chemical mechanical polishing apparatus according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Embodiments described herein are example embodiments, and thus, the disclosure is not limited thereto.

In order to clarify the present disclosure, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

Hereinafter, an embodiment of the present disclosure will be described in detail so that a person of an ordinary skill can easily practice it in the technical field to which the present disclosure belongs. However, the present disclosure may be implemented in many different forms and is not limited to the embodiments described herein.

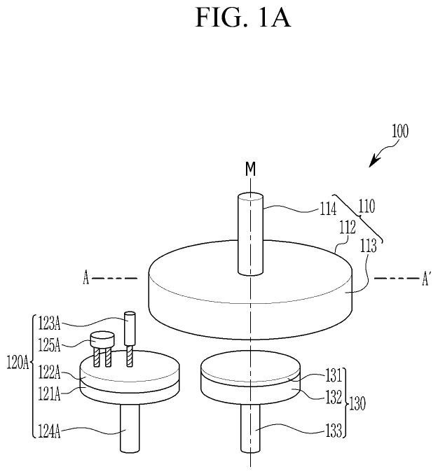

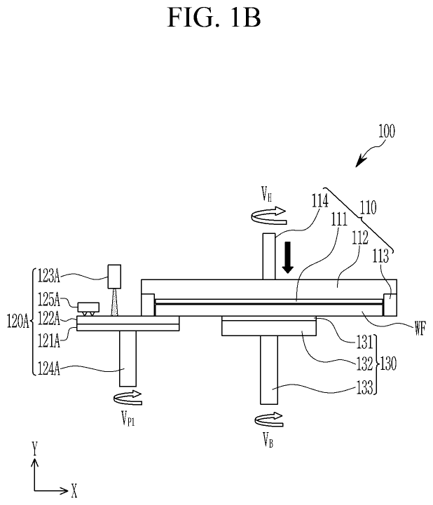

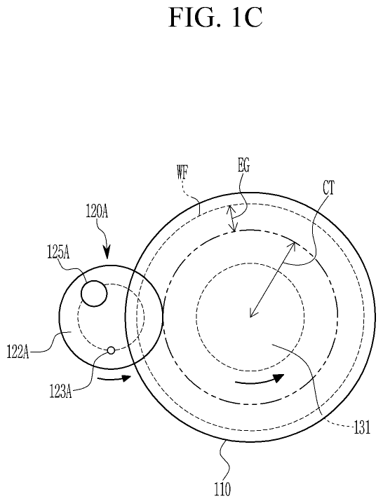

FIG. 1A is a perspective view of a chemical mechanical polishing apparatus according to an embodiment, FIG. 1B is a cross-sectional view of a chemical mechanical polishing apparatus of FIG. 1A taken along a direction A-A′, and FIG. 1C is a top plan view of a chemical mechanical polishing apparatus of FIG. 1A. However, for better comprehension, FIG. 1A shows an appearance before an operation, and FIG. 1B and FIG. 1C show an appearance during an operation.

Referring to FIG. 1A to FIG. 1C, a chemical mechanical polishing apparatus 100 is an apparatus for polishing a wafer WF and includes a head part 110, a first polishing part 120A, and a buffer part 130. The chemical mechanical polishing apparatus 100 performs mechanical polishing as the edge EG of the wafer WF mounted on the lower surface of the head part 110 is in contact with the first polishing part 120A, and chemical polishing through a chemical reaction by a slurry supplied from the first polishing part 120A.

The head part 110 may be a rotatable member and the wafer WF may be mounted on the head part 110. The head part 110 may support the wafer WF. In an embodiment, the head part 110 may be disposed on the first polishing part 120A and the buffer part 130. In an embodiment, the head part 110 may include a membrane 111 disposed on the wafer WF such that a surface of the membrane 111 is exposed and in contact with the wafer WF, a supporting plate 112 disposed on the membrane 111 and supporting the wafer WF and the membrane 111, a slip preventing part 113 extending from the end of the supporting plate 112 in the direction of the wafer WF and preventing the wafer WF from slipping and becoming detached, and a head driver 114 rotating the head part 110.

The wafer WF may include a central region and an edge region. For example, the polishing portion of the wafer WF polished by the chemical mechanical polishing apparatus 100 according to an embodiment may be the edge EG of the wafer WF. As the head part 110 rotates, the polishing portion, which is the edge EG of the wafer WF, may be mechanically polished.

In an embodiment, the edge EG may be an edge region of the front surface or the rear surface of the wafer WF. When the edge EG is the edge region of the front surface of the wafer WF, the front surface of the wafer WF on which the membrane material is deposited may be polished. When the edge EG is the edge region on the rear side of the wafer WF, the rear side of the wafer WF where a bevel film remains on the edge may be polished.

The membrane 111 is attached by the wafer WF and may control the external force according to the area of the wafer WF. For example, the membrane 111 may be a flexible material and may be a member that assists in applying an independently controllable pressure to relevant regions on the wafer WF by a plurality of independently controllable pressurization chambers.

The slip preventing part 113 may be a member preventing the wafer WF from slipping and becoming detached. For example, the slip preventing part 113 may be implemented in a ring shape surrounding the wafer WF, and may be disposed on the outside of the wafer WF to prevent the wafer WF from being detached that may occur during the polishing process.

The supporting plate 112 may be a member for supporting the wafer WF and the membrane 111. For example, the supporting plate 112 may be disposed on the lower surface of the membrane 111 to fix and support the wafer WF and the membrane 111.

The driver 114 may be a member that controls the head part 110 to be rotatable. In an embodiment, the head part 110 may be rotatable by a first controller. For example, the first controller may control the wafer WF mounted on the head part 110 to be rotatable by making the head part 110, for example, the central axis of the head part 110, rotatable. The driver 114 may include a motor.

In an embodiment, the head part 110 may be rotated at a speed VH. By rotating at the speed VH, the wafer WF may be rotated, such that the wafer WF, for example the edge EG of the wafer WF, may be polished. In an embodiment, a rotation axis M, which is a central axis of the head part 110, may be disposed perpendicular to the surface of the wafer WF. When the rotation axis M of the wafer WF and the head part 110 are perpendicular, the edge EG of the wafer WF may be polished flat.

The first polishing part 120A may be a rotatable member disposed on the edge EG of the wafer WF. The first polishing part 120A includes a first polishing platen 121A, a first polishing pad 122A disposed on the first polishing platen 121A, and a first slurry supplier 123A supplying the slurry to the first polishing pad 122A.

The rotation energy may be applied to the first polishing platen 121A such that the first polishing pad 122A rotates in a certain direction. The first polishing pad 122A is disposed on the first polishing platen 121A, and may be rotated the first polishing platen 121A being driven.

The first polishing pad 122A may uniformly planarize the surface of the wafer WF, and may be a member that performs the mechanical polishing. In an embodiment, while the first polishing pad 122A may be disposed on the first polishing platen 121A, a portion thereof may be disposed to be in contact with the edge EG of the wafer WF in the head part 110. When the first polishing platen 121A and the head part 110 rotate, the edge EG of the wafer WF may be polished.

In an embodiment, the first polishing pad 122A may perform the polishing by targeting the edges of the front surface or rear surface of the wafer WF. For example, in the case of polishing the front surface of the wafer WF, the polishing may be performed by targeting the edge of the front surface of the wafer WF on which a deposition material is deposited, and in the case of polishing the rear surface of the wafer WF, in the process of depositing the deposition material on the front surface of the wafer WF, a bevel layer on which the deposition material is partially accumulated on the edge of the rear surface of the wafer WF may be polished.

The slurry supplier 123A may be a member that supplies the slurry to the first polishing platen 121A. The slurry supplier 123A is disposed on the first polishing platen 121A, and may be a member that supplies the slurry to the first polishing platen 121A. In the chemical mechanical polishing apparatus 100, not only the mechanical polishing by the rotation of the head part 110 and the first polishing part 120A, but also the chemical polishing by the slurry may be performed simultaneously.

In an embodiment, the first polishing part 120A includes a first polishing driver 124A. The first polishing driver 123A may be a controllable member to rotate the first polishing part 120A at the speed VP1 of the first polishing part. In an embodiment, the first polishing driver 124A may be rotatable by a second controller. For example, the second controller may control the first polishing part 120A, for example, the central axis of the first polishing part 120A, to be rotatable, such that the first polishing pad 122A of the first polishing part 120A is rotatable, thereby controlling to perform the polishing by engaging with the edge EG of the wafer WF mounted on the head part 110.

In an embodiment, the first polishing part 120A further includes a conditioner 125A. The conditioner 125A may be a member that conditions the surface of the first polishing pad 122A. For example, the conditioner 125A may maintain a surface roughness of the first polishing pad 122A in an optimal state by polishing the surface of the first polishing pad 122A.

In an embodiment, the conditioner 125A may restore or maintain the surface roughness of the first polishing pad 122A by polishing the first polishing pad 122A in a state of polishing the wafer WF with the head part 110 or in a state where the polishing of the wafer WF is stopped. In an embodiment, the conditioner 125A may be configured by fixing particles for polishing, for example, artificial diamond particles, by using a nickel (Ni) adhesive layer as a medium on a circular disk made of a metal. In an embodiment, the conditioner 125A may be rotated in a certain direction. For example, the conditioner 125A may control the roughness of the first polishing pad 122A by rotating in a clockwise direction.

In an embodiment, the first polishing part 120A may have a size that is smaller than or equal to the head part 110. For example, since the first polishing part 120A has the size that is smaller than or equal to that of the head part 110, there is an advantage in that the wafer WF edge EG in the head part 110 is disposed to be in contact with a part of the first polishing part 120A and polished.

The buffer part 130 may be a rotatable member facing the head part 110 of the wafer WF and supporting the center CT of the wafer WF. The buffer part 130 may be disposed under the center CT of a surface of the wafer WF of the head part 110, and may be disposed on the same line as the first polishing part 120A in the x-axis direction. By disposing the buffer part 130 at the above-mentioned position, it is possible to prevent the wafer WF from being detached from the head part 110 due to pressure and torque applied to the head part 110.

In an embodiment, the buffer part 130 may be disposed facing the head part 110. Prior to the wafer WF is mounted on the head part 110, the buffer part 130 and the head part 110 may be disposed facing each other to be spaced apart by a predetermined distance, the wafer WF may be mounted on the head part 110, and the buffer part 130 and the wafer WF of the head part 110 may be disposed to be in contact with each other for polishing.

In an embodiment, the buffer part 130 may be a member including a buffer plate 131 that is a soft material in contact with the wafer WF, a supporting plate 132 supporting the buffer plate 131, and a buffer driver 133 that drives the buffer part 130. The buffer part 130 may be designed to be rotatable in contact with the wafer WF.

In an embodiment, the buffer plate 131 may be composed of a soft material. The buffer plate 131 is formed of the soft material, such that a problem of polishing portions other than the edge EG of the wafer WF, which is the polishing portion, may not occur even when the wafer WF rotates in contact with the buffer plate 131. The soft material may include, but is not limited to, polyvinyl chloride, polyvinyl fluoride, nylon, fluorocarbon, polycarbonate, polyester, polyacrylate, polyether, polyethylene, polyamide, polyurethane, polystyrene, polypropylene, co-forming products thereof, or mixtures thereof.

In an embodiment, the buffer part 130 may rotate at a speed VB of the buffer part. In an embodiment, the speed VB of the buffer part may be controlled at the same speed as the speed VH of the head part 110. As the speed VB of the buffer part and the speed VH of the head part 110 are controlled at the same speed, the frictional force between the wafer WF and the buffer part VB in the head part 110 may be minimized and only the edge EG, which is the polishing portion of the wafer WF, may be finely polished.

In another embodiment, the speed VB of the buffer part 130 may be controlled at a different speed from the speed VH of the head part 110. By rotating at the speed VB of the buffer part 130 and the speed VH of the head part to be different, by-products such as particles generated from the edge EG, which is the polishing portion, may be removed.

The buffer supporting plate 132 may be a member to which the buffer plate 131, which is a soft material, is fixed. The buffer driver 133 is a member that drives the buffer part 130 and may be rotatable by a third controller. For example, the third controller may control the central axis of the buffer part 130 to be rotatable, such that while the head part 110 rotates, the edge EG of the wafer WF may be simultaneously polished and the interference may be minimized on other parts.

In an embodiment, the buffer part 130 may be controlled such that the pressure applied by the membrane 111 on the head part 110 is smaller than the pressure applied by the membrane 111 on the edge EG. The membrane 111 may be composed of each pressure chamber, and for example, may control the pressure of the membrane 111 so that the center CT and the edge EG of the wafer WF are respectively applied with different pressures. For example, the pressure of the membrane 111 may be controlled such that different pressures are applied to the center CT of the wafer WF.

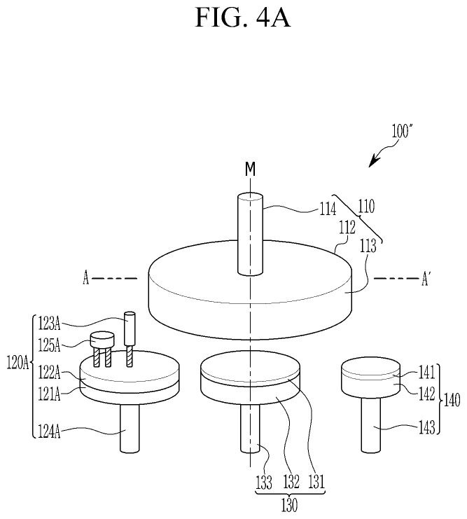

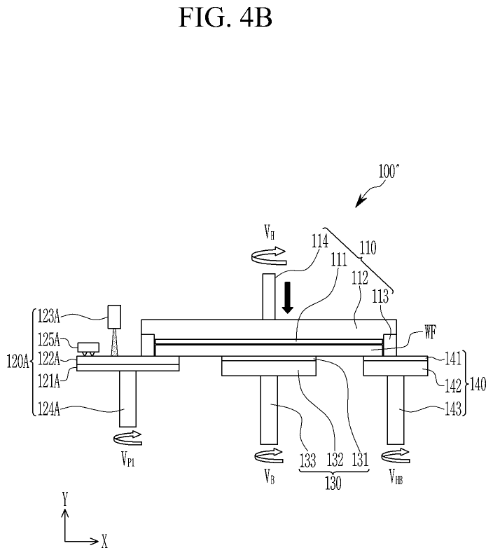

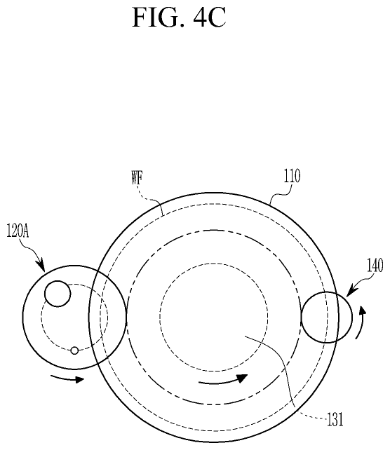

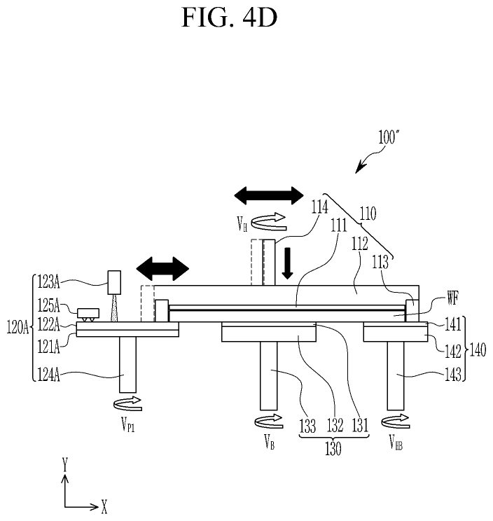

In an embodiment, the center axis (the rotation axis) of the buffer part 130 and the center axis (the rotation axis) of the head part 110 may be arranged on the same axis M. By rotating the buffer part 130 and the head part 110 with the reference to the same axis M in the engagement, tilting of the wafer WF may be prevented. In another embodiment, as the head part 110 is moved in the radial direction of the wafer, the rotation axis of the buffer part 130 and the rotation axis of the head part 110 may not be arranged on the same axis, but may be arranged side by side (referring to FIG. 4D).

In an embodiment, the buffer part 130 may be disposed to be spaced apart from the first polishing part 120A. For example, the buffer part 130 may be disposed to engage and may be in contact with the center CT of the wafer WF and the first polishing part 120A may be disposed to engage and may be in contact with the edge EG of the wafer WF, such that the buffer part 130 and the first polishing part 120A may be disposed to be spaced apart. As the buffer part 130 and the first polishing part 120A are disposed to be spaced apart, the interference with the polishing performance of the first polishing part 120A may be minimized, and it may be prevented that by-products after the polishing of the wafer WF, which may occur from the first polishing part 120A, cause the interference with the buffer part 130, and then the center CT of the wafer WF is interfered with regardless of the polishing portion.

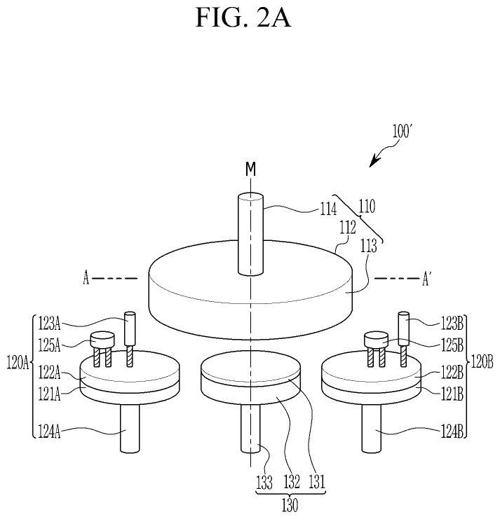

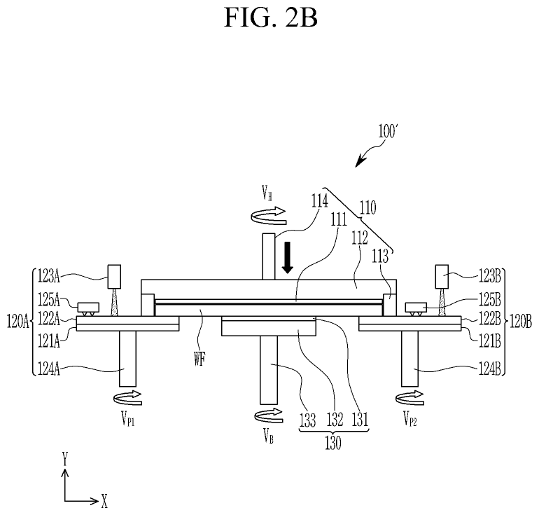

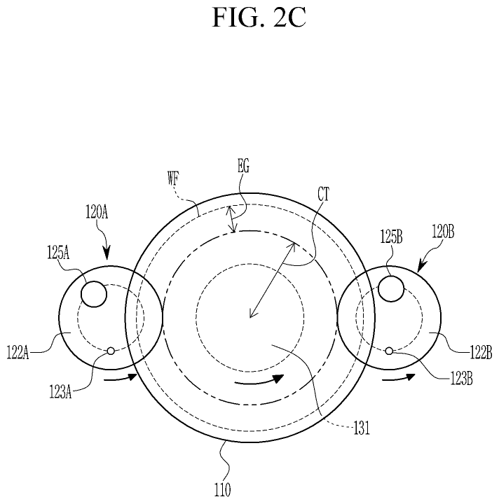

FIG. 2A is a perspective view of a chemical mechanical polishing apparatus according to another embodiment, FIG. 2B is a cross-sectional view of a chemical mechanical polishing apparatus taken along a direction A-A′ of FIG. 2A, and FIG. 2C is a top plan view of a chemical mechanical polishing apparatus of FIG. 2A.

Referring to FIG. 2A to FIG. 2C, a chemical mechanical polishing apparatus 100′ that is a device of polishing the wafer WF may include a second polishing part 120B arranged symmetrically with the first polishing part 120A with the rotation axis M of the buffer part 130. In addition to the first polishing part 120A, the second polishing part 120B is disposed symmetrically with the first polishing part 120A, so that the tilting of the head part 110 may be prevented and the polishing of the edge EG of the wafer WF may be performed more precisely. The detailed description of the second polishing part 120B is identical to the first polishing part 120A to the extent that it does not contradict.

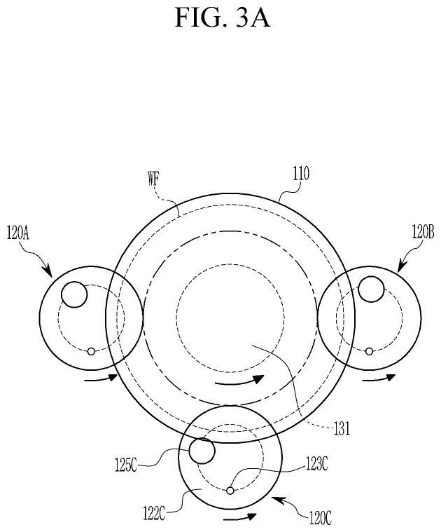

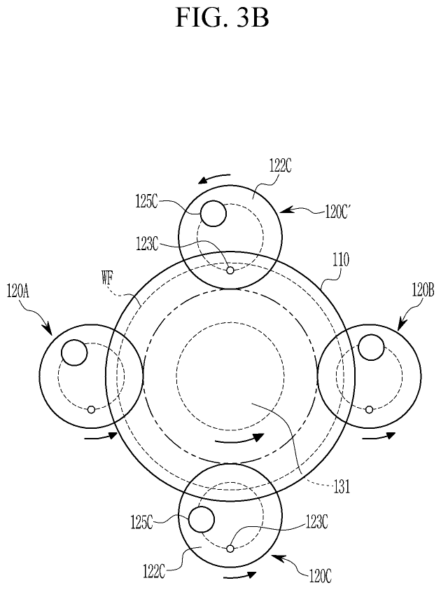

FIG. 3A and FIG. 3B are top plan views of a chemical mechanical polishing apparatus according to an embodiment.

Referring to FIG. 3A, a chemical mechanical polishing apparatus 100′ may include at least one dummy polishing part 120C disposed under the edge EG of the wafer WF and placed between the first polishing part 120A and the second polishing part 120B. The dummy polishing part 120C is disposed under the edge EG of the wafer WF, and the first polishing part 120A, the second polishing part 120B, and the dummy polishing part 120C are disposed under the circumference of the edge EG of the wafer WF, such the polishing of the edge EG of the wafer WF may be performed more elaborately. The detailed composition of the dummy polishing part 120C is the same as the first polishing part 120A to the extent that it does not contradict the second polishing part 120B.

Referring to FIG. 3B, the chemical mechanical polishing apparatus 100′ may include a plurality of dummy polishing parts 120C and 120C′. As shown in FIG. 3B, a plurality of dummy polishing parts 120C and 120C′ may be disposed to be perpendicular to the first polishing part 120A and the second polishing part 120B. As a plurality of dummy polishing parts 120C and 120C′ are disposed as shown in FIG. 3B for the polishing of the wafer WF, the tilting of the wafer WF may be prevented and the polishing may be performed with more stability. Since FIG. 3B does not limit the present disclosure, the dummy polishing parts 120C and 120C′ may be disposed between the first polishing part 120A and the second polishing part 120B in a range that does not interfere with the first polishing part 120A and the second polishing part 120B.

FIG. 4A is a perspective view of a chemical mechanical polishing apparatus according to another embodiment, FIG. 4B is a cross-section of a chemical mechanical polishing apparatus of FIG. 4A taken along a direction A-A′, FIG. 4C is a top plan view of a chemical mechanical polishing apparatus of FIGS. 4A, and 4D is a view showing that a head part is swept.

Referring to FIG. 4A to FIG. 4C, a chemical mechanical polishing apparatus 100″ may include a rotatable head part 110 and the wafer WF may be mounted on the rotatable head part 110 with a surface being exposed, a rotatable buffer part 130 facing the head part 110 and supporting the center CT of the one side of the wafer WF, a first polishing part 120A, which is spaced apart from the buffer part 130 in the radial direction of the wafer WF and disposed to the edge EG of a surface of the wafer WF, and a head supporting part 140 arranged symmetrically with the first polishing part 120A with respect to the rotation axis of the buffer part 130 and supporting the head part 110. The detailed description of the head part 110, the first polishing part 120A, and the buffer part 130 is the same as described in the above-mentioned FIG. 1A to FIG. 1C in a range that does not contradict.

The head supporting part 140 may be a member that is disposed symmetrically with the first polishing part 120A with the rotation axis M of the buffer part 130 as a reference, and supports the head part 110 in contact with a part of the edge EG of the wafer WF. The head supporting part 140 is disposed symmetrically with the first polishing part 120A, simultaneously disposed in contact with a part of the edge EF of the wafer WF, thereby being disposed on the same line with the buffer part 130 in the x-axis direction, and thereby preventing the detachment and tilting of the wafer WF.

In an embodiment, the head supporting part 140 may include a contact plate 141, which is a soft material in contact with the edge EG of the wafer WF, a head supporting plate 142 supporting the contact plate 141, and a supporting driver 143 that drives the head supporting plate 142. The soft material of the contact plate 141 is, as non-limiting examples, polyvinyl chloride, polyvinyl fluoride, nylon, fluorocarbon, polycarbonate, polyester, polyacrylate, polyether, polyethylene, polyamide, polyurethane, polystyrene, polypropylene, a co-forming product thereof, or a mixture thereof.

The head supporting plate 142 may be a member to which the soft material contact plate 141 is fixed. The supporting driver 143 is a member that drives the head supporting part 140 and may be rotatable by a fourth controller. For example, the fourth controller may support the head part 110 by making the central axis of the head supporting part 140 rotatable and rotating the head supporting part 140 at the rotation speed VHB of the head supporting part.

Referring to FIG. 4D, in an embodiment, the head part 110 may be movable in a radial direction of the wafer WF. For example, the head part 110 may move in a direction that is different from the rotation axis M of the buffer part 130. More For example, the head part 110 may move in a direction perpendicular to the rotation axis M of the buffer part 130.

FIG. 4D shows that the head part 110 moves in a direction parallel to the wafer WF in a state where the first polishing part 120A, the buffer part 130, and the head supporting part 140 are fixed. In the state that the first polishing part 120A, the buffer part 130, and the head supporting part 140 are fixed, as only the head part 110 moves in the left and right directions (the x-axis direction), the edge EG, which is the polishing portion of the wafer WF, may be adjusted more precisely. For example, when trying to make the polishing portion wider, the head part 110 may be moved in the arranged direction (the −x-axis direction) of the first polishing part 120A, and when trying to make the polishing portion narrower, the head part 110 may be moved in the direction (the x direction) where the head supporting part 140 is disposed.

In this way, in the state that the first polishing part 120A, the buffer part 130, and the head supporting part 140 are fixed, the head part 110 moves in the direction parallel to the wafer WF, thereby more stably polishing portion without detachment or tilting of the head part 110 may be controlled.

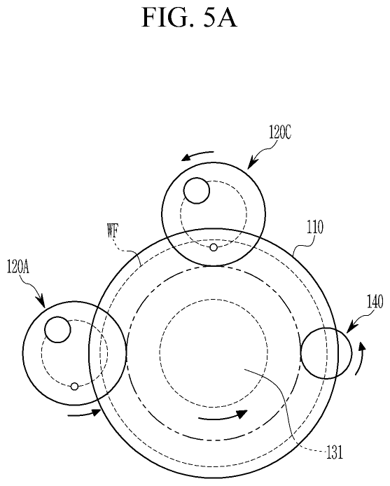

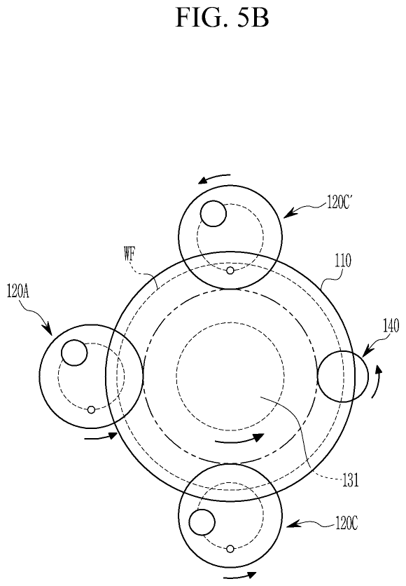

FIG. 5A and FIG. 5B are top plan views of a chemical mechanical polishing apparatus according to another embodiment.

Referring to FIG. 5A, in an embodiment, the chemical mechanical polishing apparatus 100″ may include at least one dummy polishing part 120C disposed under the edge EG of the wafer WF and disposed between the first polishing part 120A and the head supporting part 140. The dummy polishing part 120C is disposed under the edge EG of the wafer WF, the first polishing part 120A, the head supporting part 140 and the dummy polishing part 120C are disposed under the circumferential direction of the edge EG of the wafer WF, and the polishing of the edge EG of the wafer WF may be performed more elaborately.

Referring to FIG. 5B, the chemical mechanical polishing apparatus 100″ may include a plurality of dummy polishing parts 120C and 120C′. As shown in FIG. 5B, the plurality of dummy polishing parts 120C and 120C′ may be disposed to be perpendicular to the first polishing part 120A and the head supporting part 140. As the plurality of dummy polishing parts 120C and 120C′ are disposed as shown in FIG. 5B, in performing the polishing of the wafer WF, it is possible to perform the polishing with greater stability while preventing the tilting of the wafer WF.

However, embodiments are not limited thereto, and the dummy polishing parts 120C and 120C′ may be disposed between the first polishing part 120A and the head supporting part 140 in a range that does not interfere with the first polishing part 120A and the head supporting part 140. A detailed description of the dummy polishing unit 120C is the same as that of the first polishing unit 120A described above with reference to FIGS. 1A to 1C to the extent that it does not contradict.

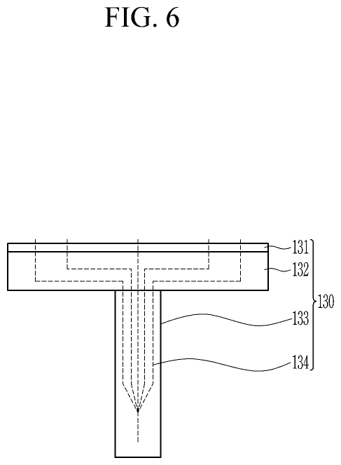

FIG. 6 is a view showing a buffer part according to an embodiment.

Referring to FIG. 6, the buffer part 130 may further include a spray nozzle 134 disposed in the buffer part 130 and spraying a cleaning material to the wafer WF. In the buffer part 130, a pipe is formed inside the buffer part 130, and a cleaning material, for example, a material such as DI water, may be supplied to the pipe. The cleaning material may be supplied to the pipe and sprayed to the wafer WF engaged with the buffer part 130 along the spray nozzle 134 of the cleaning material supplied to the pipe. The cleaning material may be supplied to the wafer WF without limitation when the buffer part 130 and the head part 110 perform the rotation or do not perform the rotation. As the cleaning material is supplied through the spray nozzle 134 of the buffer part 130, the movement of impurities that may be supplied from the edge EG of the wafer WF to the center CT may be suppressed or removed.

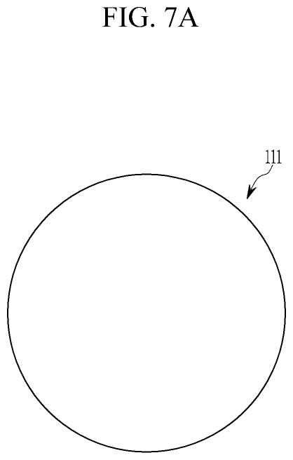

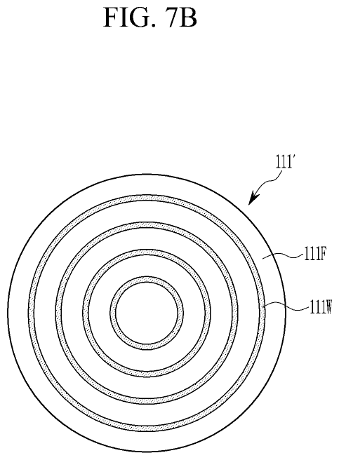

FIG. 7A to FIG. 7C are views showing a pattern of a membrane according to an embodiment.

FIG. 7A to FIG. 7C are the rear views when viewing in the +y-axis direction in the state in which the wafer is not mounted on the head part 110 in FIG. 1A. Referring to FIG. 7A, the membrane 111 is disposed on the supporting plate 112 supporting the membrane 111, and may be a circular member having a diameter that is greater than or equal to the diameter of the wafer WF. The membrane 111 may be disposed in contact with the center CT, the middle portion, and the edge EG of the wafer WF, and the pressure may be differently controlled for each portion.

Referring to FIG. 7B, in an embodiment, the membrane 111′ may include at least one barrier rib part 111W partitioning a region of the membrane 111′. For example, the barrier rib part 111W may be arranged in a concentric circle to partition the membrane 111′.

In an embodiment, a plurality of regions of the membrane 111′ partitioned into the barrier rib part 111W may be independently driven. In an embodiment, the barrier rib part 111W may be a temporary wall made of silicon. By partitioning the membrane 111′ into a plurality of regions by the temporary wall, the pressure applied to the membrane 111′ may be set more precisely. In an embodiment, when there are a plurality of barrier rib parts 111W, the distances between the barrier rib parts 111W may be the same or different. By setting the same or different spacing between the barrier rib part 111W, the various types of membrane 111′ patterns may be implemented.

Referring to FIG. 7C, in an embodiment, at least one barrier rib part 111W may be disposed facing the edge EG of the wafer WF. As the barrier rib part 111W is disposed in the region EG′ facing the edge EG of the wafer WF, the membrane 111′ is patterned in the region EG′ facing the edge EG of the wafer WF to perform the pressure control more precisely, therefore, the edge EG of the wafer WF may be polished more precisely. In FIG. 7C, three barrier rib parts 111W are shown, but embodiments are not limited thereto.

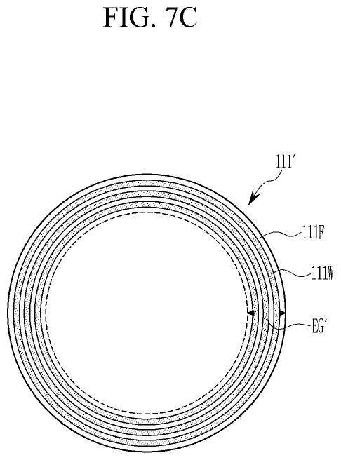

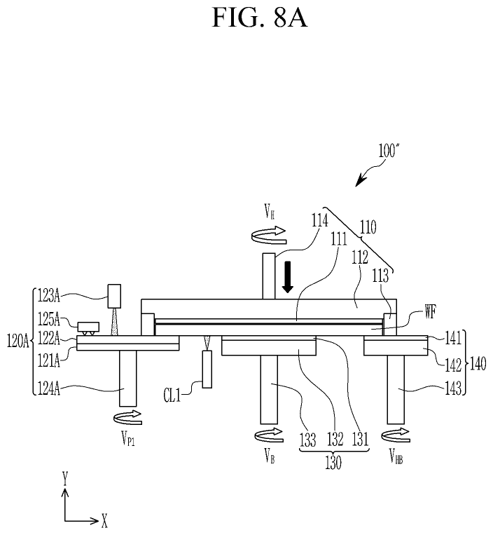

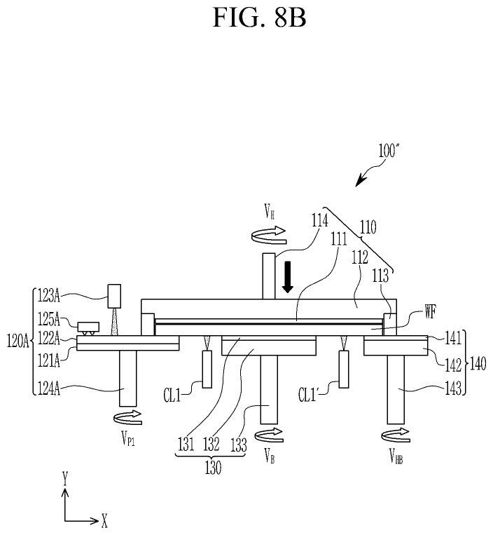

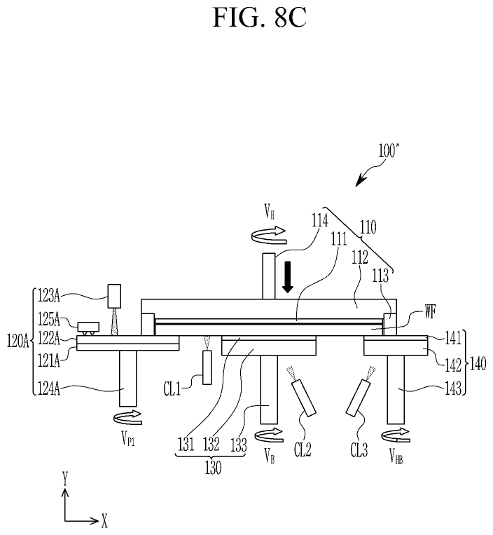

FIG. 8A to FIG. 8C are views showing a chemical mechanical polishing apparatus including a cleaning part according to an embodiment.

Referring to FIG. 8A, in an embodiment, the first cleaning part CL1 is disposed between the first polishing part 120A and the buffer part 130, and the cleaning material may be supplied in the wafer WF direction. The cleaning material may be, for example, air or DI water, and may for example form an air curtain.

As the first cleaning part CL1 is disposed between the first polishing part 120A and the buffer part 130, it is possible to prevent by-products generated as the edge EG of the wafer WF is polished from diverging to the buffer part 130 as the head part 110 and first polishing part 120A are rotated. By disposing the first cleaning part CL1 between the first polishing part 120A and the buffer part 130, it is possible to prevent a problem of the transferring of by-products from the buffer part 130 or the center of the wafer WF in contact with the buffer part 130. The first cleaning part CL1 may supply the cleaning materials in the wafer WF direction.

FIG. 8A discloses that the cleaning material is supplied to the wafer WF in a direction (the +y direction) perpendicular to a direction parallel to the wafer WF, but embodiments are not limited thereto. When the by-product is prevented from reaching the buffer part 130, a predetermined angle with respect to the direction parallel to the wafer WF may be formed.

Referring to FIG. 8B, in an embodiment, at least one first cleaning part of CL1 and CL1′ is disposed along the rotation direction of the wafer WF between the first polishing part 120A and the buffer part 130, and the buffer part 130 and the head supporting part 140, and the cleaning material may be supplied in the wafer WF direction. In FIG. 8B, a plurality of first cleaning parts CL1 and CL1′ are symmetrically disposed between the first polishing part 120A and the buffer part 130, and the buffer part 130 and the head supporting part 140 with reference to the axial direction of the buffer part 130, respectively, but embodiments are not limited thereto. For example, the a plurality of first cleaning parts CL1 and CL1′ may be disposed in a range that does not interfere with the first polishing part 120A, the buffer part 130, and the head supporting part 140.

Referring to FIG. 8C, in an embodiment, the second cleaning part CL2 may supply the cleaning material to the buffer part 130. For example, the second cleaning part CL2 may directly supply the cleaning material to the buffer part 130. For example, the second cleaning part CL2 may be a member that additionally filters byproducts not filtered out by the first cleaning part CL1.

In an embodiment, the third cleaning part CL3 may supply cleaning material to the head supporting part 140. For example, the third cleaning part CL3 directly supplies the cleaning material to the head supporting part 140, and as the head part 110 rotates, by-products such as slurry dregs generated in the first polishing part 120A may be transported to the head supporting part 140, and at this time, by using the third cleaning part CL3 to remove the by-products, the polishing of the edge EG of the wafer WF, which is the polishing portion, may be performed more precisely.

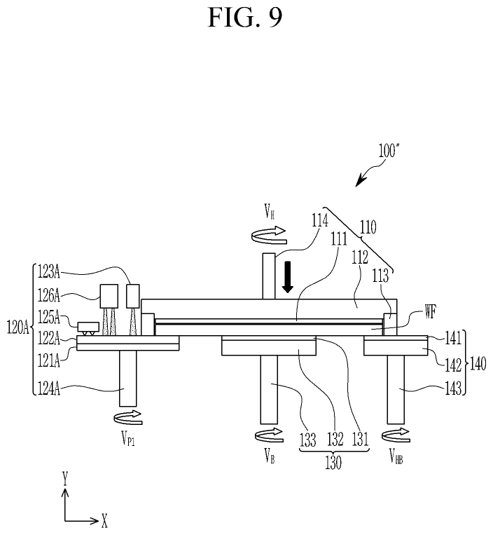

FIG. 9 is a view showing a chemical mechanical polishing apparatus including a temperature controller 126A according to an embodiment.

Referring to FIG. 9, the chemical mechanical polishing apparatus 100″ according to an embodiment may include a temperature controller 126A disposed on the first polishing part 120A to measure and control the temperature of the first polishing part 120A. The temperature controller 126A may measure a temperature variable in the process of the chemical mechanical polishing and may be controlled through a first controller to control the rotation speed VP1 of the polishing part 120A according to the measured temperature.

For example, when the temperature of the polishing part 120A, for example, the polishing pad 121A, is excessively high, the rotation speed VP1 of the polishing part 120A may be lowered through the first controller, and when the temperature of the polishing pad 121A is excessively low, the rotation speed VP2 of the polishing part 120A may be lowered through the first controller. As such, the chemical mechanical polishing apparatus 100″ includes the temperature controller 126A, such that the temperature of the first polishing part 120A, for example, the first polishing pad 121A, may be measured to infer the temperature of the chemical mechanical polishing apparatus 100″, and according to the inferred temperature, the temperature of the chemical mechanical polishing apparatus 100″ may be controlled by controlling the rotation speed VP1 of the first polishing part 120A.

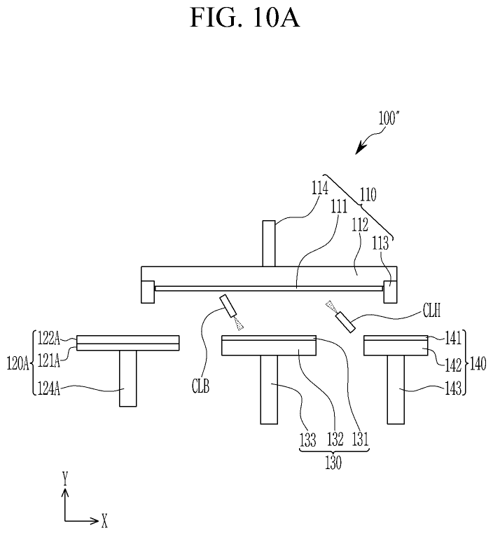

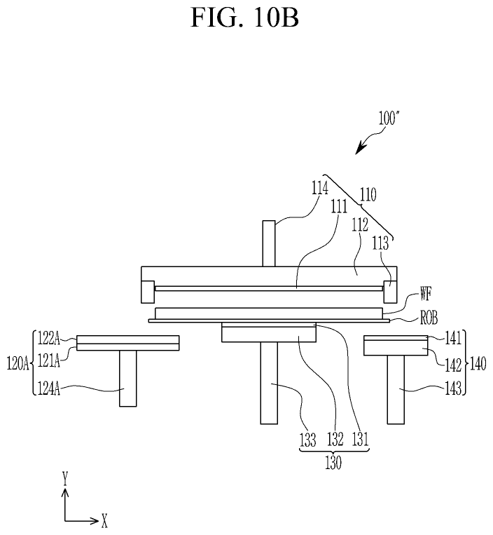

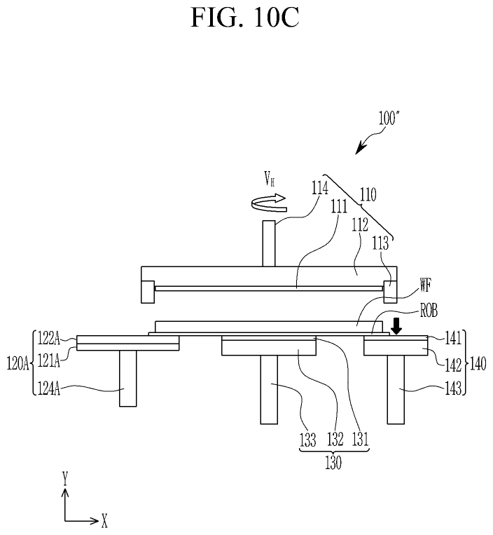

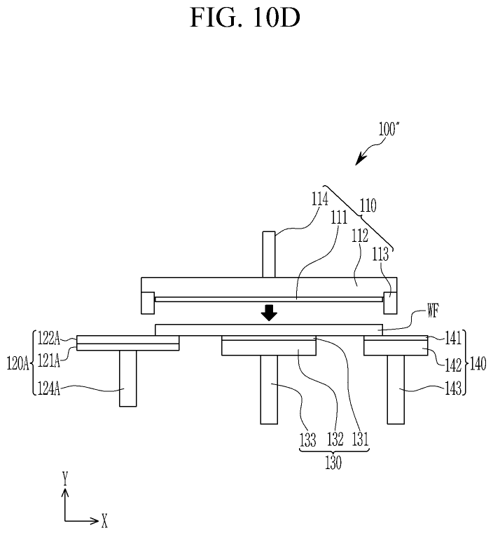

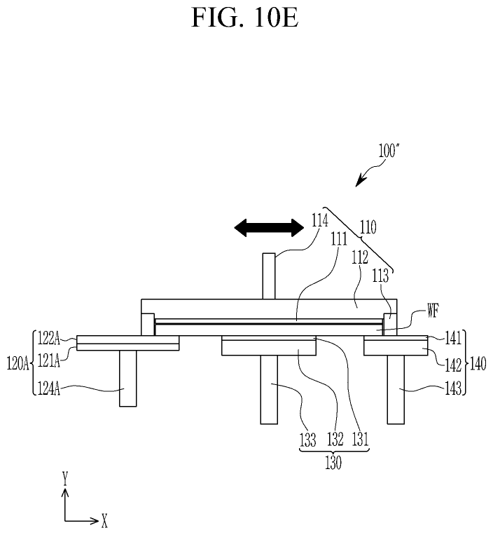

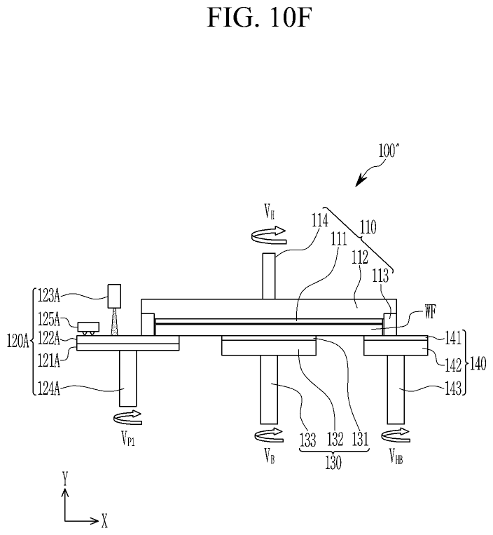

FIG. 10A to FIG. 10F are views showing a control method of a chemical mechanical polishing apparatus according to an embodiment.

FIG. 10A shows a step of disposing a head part 110 on which a wafer is not mounted on a buffer part 130. The head part 110 and the buffer part 130 may be disposed to be spaced apart such that the wafer WF may be disposed between the head part 110 and the buffer part 130 before the wafer is mounted. In FIG. 10A, the first polishing part 120A and the head supporting part 140 are fixed and disposed on the same line as the buffer part 130, but embodiments are not limited thereto, and the first polishing part 120A and the second polishing part 120B may be fixed and disposed, the first polishing part 120A, the second polishing part 120B, and at least one dummy polishing part 120C may be fixed and disposed, or the first polishing part 120A, the head supporting part 140, and at least one dummy polishing part 120 may be fixed and disposed.

In an embodiment, the step of disposing the head part 110 on which the wafer is not mounted on the buffer part 130 include a step of cleaning the head part 110 and the buffer part 130 by using the head cleaning part CLH and the buffer cleaning part CLB in the state where the wafer is not mounted. By going through the step of cleaning the head part 110 and the buffer part 130 before the wafer is mounted, the wafer WF may be more precisely in contact with the membrane 111 without the tilting due to impurities, and unwanted polishing or damage to the center of the wafer WF may be prevented from occurring due to the impurity remaining in the buffer part 130.

FIG. 10B shows a step of loading the wafer WF onto the buffer part 130 by transporting the wafer WF between the head part 110 and the buffer part 130. In an embodiment, the step of loading the wafer WF onto the buffer part 130 by transporting the wafer WF between the head part 110 and the buffer part 130 may be performed by a transport robot ROB.

In FIG. 10C, the wafer WF may be placed on the buffer plate 131 by the transport robot ROB. The transport robot ROB may be, for example, a two-legged robot member capable of supporting the edge EG of the wafer WF. In an embodiment, the distance between two legs may be greater than the diameter of the buffer plate 131. When the distance between the two legs of the transport robot ROB is greater than the diameter of the buffer plate 131, the transport robot ROB may seat the wafer WF on the buffer plate 131 without additional interference.

In FIG. 10D, the wafer WF may be separated after being placed on the buffer plate 131 by the transport robot ROB. When the distance between two legs of the transport robot ROB is greater than the diameter of the buffer plate 131 as described above, they may be removed without interference with other members.

FIG. 10E shows a step in which the loaded wafer WF is in contact with the membrane 111 disposed in the head part 110. The head part 110 disposed on the wafer WF seated in the buffer part 130 moves in the downward direction such that the membrane 111 in the head part 110 and the wafer WF may face each other and be in contact with each other.

In an embodiment, after the step in which the loaded wafer WF is in contact with the membrane 111 disposed within the head part 110, a step of moving the head part 110 in a direction parallel to the wafer WF may be included which may include a step of moving the head part 110 in a direction parallel to the wafer WF, for example, in the x-axis direction. The region of the polishing portion of the wafer WF may be controlled by including the step of moving the head part 110 in the direction parallel to the wafer WF. In an embodiment, the step of moving the head part 110 in the direction parallel to the wafer WF may be performed before the step in which the slurry is supplied from the first slurry supplier 123A to the first polishing pad 122A or in the step in which the slurry is supplied from the first slurry supplier 123A to the first polishing pad 122A.

FIG. 10F shows a step in which the slurry is supplied from the first slurry supplier 123A onto the first polishing pad 122A and a step in which the first polishing pad 122A and the head part 110 rotate and polish the edge of the wafer WF. In an embodiment, the control method of the chemical mechanical polishing apparatus may further include a step of disposing the second polishing part 120B or the head supporting part 140. In another embodiment, the step of disposing of the second polishing part 120B or the head supporting part 140 may further include a step of disposing at least one dummy polishing part 120C. In the aforementioned manufacturing method, the detailed description of each component may refer to the aforementioned FIG. 1A to FIG. 9.

The present disclosure is not limited to the embodiments, but may be manufactured in a variety of different forms, and those of ordinary skill in the art to which the present disclosure pertains will understand that the present disclosure may be implemented in other specific forms without changing the technical spirit or essential features of the present disclosure. Therefore, it should be understood that the above-mentioned embodiments are just examples in all aspects and are not limited thereto. While embodiments have been described with reference to the figures, it will be understood by those of ordinary skill in the art that various changes in form and details may be made therein without departing from the spirit and scope as defined by the following claims and their equivalents.

What is claimed is:

1. A chemical mechanical polishing apparatus comprising:
a head part configured to support a wafer;
a buffer part on the head part and configured to support a center of the wafer; and
a first polishing part that is spaced apart from the buffer part and configured to be on an edge of the wafer.

2. The chemical mechanical polishing apparatus of claim 1, further comprising a second polishing part symmetric with the first polishing part with respect to a rotation axis of the buffer part.

3. The chemical mechanical polishing apparatus of claim 2, further comprising at least one dummy polishing part on the edge of the wafer, the at least one dummy polishing part being between the first polishing part and the second polishing part.

4. The chemical mechanical polishing apparatus of claim 3, wherein the first polishing part, the second polishing part, and the at least one dummy polishing part respectively comprise a polishing platen, a polishing pad on the polishing platen, and a slurry supplier configured to supply a slurry to the polishing pad.

5. The chemical mechanical polishing apparatus of claim 1, wherein the buffer part comprises:
a buffer plate that comprises a soft material and in contact with the wafer;
a supporting plate on the buffer plate; and
a buffer driver configured to drive the buffer part.

6. The chemical mechanical polishing apparatus of claim 1, wherein a rotation speed of the head part and a rotation speed of the buffer part are different.

7. The chemical mechanical polishing apparatus of claim 1, further comprising a spray nozzle in the buffer part and configured to spray a cleaning material to the wafer.

8. The chemical mechanical polishing apparatus of claim 1, further comprising a first cleaning part between the first polishing part and the buffer part, the first cleaning part being configured to supply a cleaning material toward the wafer.

9. The chemical mechanical polishing apparatus of claim 8, further comprising a second cleaning part configured to supply a cleaning material to the buffer part.

10. The chemical mechanical polishing apparatus of claim 1, further comprising a head supporting part symmetric with the first polishing part with respect to a rotation axis of the buffer part, the head supporting part being configured to support the head part.

11. The chemical mechanical polishing apparatus of claim 1, wherein the head part comprises:
a membrane configured to be in contact with the wafer;
a supporting plate on the membrane and configured to support the wafer and the membrane;
a slip preventing part that extends from an end of the supporting plate toward the wafer and configured to prevent separation of the wafer; and
a head driver configured to rotate the head part.

12. The chemical mechanical polishing apparatus of claim 11, wherein the membrane comprises at least one barrier rib part partitioning a region of the membrane.

13. A chemical mechanical polishing apparatus comprising:
a head part configured to support a wafer such that a surface of the wafer is exposed;
a buffer part on the head part and configured to support a center of the surface of the wafer;
a first polishing part spaced apart from the buffer part in a radial direction of the wafer and on an edge of the surface of the wafer; and
a head supporting part symmetric to the first polishing part with respect to a rotation axis of the buffer part, the head supporting part being configured to support the head part.

14. The chemical mechanical polishing apparatus of claim 13, wherein the head supporting part comprises:
a contact plate that comprises a soft material and is in contact with the edge of the wafer;
a supporting plate on the contact plate; and
a supporting driver configured to drive the supporting plate.

15. The chemical mechanical polishing apparatus of claim 13, further comprising a dummy polishing part spaced apart from the first polishing part, the buffer part, and the head supporting part,
wherein the first polishing part and the dummy polishing part each comprises a polishing platen, a polishing pad on the polishing platen, and a slurry supplier configured to supply a slurry to the polishing pad.

16. The chemical mechanical polishing apparatus of claim 13, wherein the head part is movable in the radial direction of the wafer.

17. The chemical mechanical polishing apparatus of claim 13, further comprising a third cleaning part configured to supply a cleaning material to the head supporting part.

18. The chemical mechanical polishing apparatus of claim 13, further comprising a temperature controller on the first polishing part, the temperature controller being configured to measure and control a temperature of the first polishing part.

19. A control method of a chemical mechanical polishing apparatus comprising:
disposing a head part on a buffer part;
loading a wafer on the buffer part by moving the wafer between the head part and the buffer part;
moving the loaded wafer to be in contact with a membrane in the head part;
supplying a slurry from a first slurry supplier to a first polishing pad; and
rotating the first polishing pad and the head part and polishing an edge of the wafer.

20. The control method of the chemical mechanical polishing apparatus of claim 19, further comprising moving the head part in a direction parallel to the wafer between the moving of the loaded wafer to be in contact with the membrane in the head part and the supplying the slurry to the first polishing pad from the first slurry supplier to the first polishing pad.
